(19) United States
(12) Patent Application Publication
(10) Pub. No.: US 2009/0283820 A1
(43) Pub. Date: Nov. 19, 2009

(54) NON-VOLATILE SEMICONDUCTOR MEMORY DEVICE

(76) Inventor: Toshitake YAEGASHI, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/431,306

(22) Filed: Apr. 28, 2009

(30) Foreign Application Priority Data
May 14, 2008 (JP) 2008-127020

(51) Int. Cl. H01L 29/792

(52) U.S. Cl. 257/324; 257/E29.309

(57) ABSTRACT

A non-volatile semiconductor memory device includes a memory cell array having a cell transistor and a selective transistor provided on a semiconductor substrate. The cell transistor includes a tunnel insulation film, a charge accumulation layer, a block insulation film, and a gate electrode on the substrate. The charge accumulation layer is disconnected between adjacent cell transistors. The selective transistor includes a gate insulation film and a gate electrode formed of the same material as the material of the block insulation film on the substrate. A step is provided on a surface of the substrate between the cell transistor and the selective transistor, such that the step is positioned higher on a side of the cell transistor and lower on a side of the selective transistor.

### CROSS-REFERENCE TO RELATED APPLICATIONS

This application is based upon and claims the benefit of priority from prior Japanese Patent Application No. 2008-127020, filed May 14, 2008, the entire contents of which are incorporated herein by reference.

### BACKGROUND OF THE INVENTION

1. Field of the Invention

The present invention relates to a non-volatile semiconductor memory device using an insulation film such as a silicon nitride film as a charge accumulation layer, and more particularly, to a non-volatile semiconductor memory device including a memory cell unit formed of a plurality of memory cell transistors and a memory cell array formed of a selective transistor.

2. Description of the Related Art

A Metal-Oxide-Nitride-Oxide-Silicon (MONOS) cell which uses a silicon nitride film as a charge accumulation layer is known as one type of non-volatile semiconductor memory cell. A NAND-type non-volatile semiconductor memory device to which the MONOS cell is applied is configured by forming a memory cell transistor and a selective transistor having the same configuration as that of the memory cell transistor on a flat semiconductor substrate.

In this configuration, since the selective transistor also includes a charge accumulation layer, when a number of reading operations are performed, a charge is introduced into the charge accumulation layer of the selective transistor due to the voltage stress applied to the gate electrode of the selective transistor at the time of reading. Due to this, there has been a problem of malfunction caused by change of the threshold voltage of the selective transistor (see Jpn. Pat. Appln. KOKAI Publication No. 2004-296683, for example). There has also been a problem of deterioration in data retention properties caused by movement of charge between memory cell transistors when the charge accumulation layer between the memory cell transistors is not disconnected.

In order to solve these problems, the method of providing a configuration in which a charge accumulation layer between memory cell transistors is disconnected and a gate insulation film of a selective transistor does not include a charge accumulation layer has been proposed (see Jpn. Pat. Appln. KOKAI Publication No. 2002-324860, for example). In this method, however, the step of processing the gate insulation film of the selective transistor needs to be performed separately from the step of processing of the memory cell transistor. This involves an increase in manufacturing cost and results in an increased number of steps.

### BRIEF SUMMARY OF THE INVENTION

According to one aspect of this invention, there is provided a non-volatile semiconductor memory device, comprising:

a semiconductor substrate; and

a memory cell array provided on the semiconductor substrate and formed of a memory cell unit including at least two memory cell transistors and a selective transistor provided adjacent to the memory cell unit,

wherein the memory cell transistor includes a tunnel insulation film formed on the semiconductor substrate, a charge accumulation layer formed on the tunnel insulation film, a block insulation film formed on the charge accumulation layer, and a gate electrode formed on the block insulation film, the charge accumulation layer being disconnected between the memory cell transistors,

the selective transistor includes a gate insulation film including a film made of the same material as the block insulation film and formed on the semiconductor substrate, and a gate electrode formed on the gate insulation film, and

a step is provided on a surface of the semiconductor substrate between the gate electrode of the memory cell transistor and the gate electrode of the selective transistor, the step being formed such that a surface of the semiconductor substrate on a side of the memory cell transistor is positioned higher and a surface of the semiconductor substrate on a side of the selective transistor is positioned lower.

According to another aspect of this invention, there is provided a non-volatile semiconductor memory device, comprising:

a semiconductor substrate;

a NAND cell unit provided on the semiconductor substrate and including at least two memory cell transistors, each of the memory cell transistors of the NAND cell unit including:

a tunnel insulation film formed on the semiconductor substrate;

a charge accumulation layer formed on the tunnel insulation film;

a block insulation film formed on the charge accumulation layer; and

a gate electrode formed on the block insulation film,

the charge accumulation layer being disconnected between the memory cell transistors,

a selective transistors provided adjacent to the NAND cell unit, the selective transistor including:

a gate insulation film formed of a two-layered structure including a first gate insulation film formed of a material different from a material of the tunnel insulation film of the memory cell transistor and a second gate insulation film formed of the same material as the material of the block insulation film of the memory cell transistor; and

a gate electrode formed on the gate insulation film,

wherein a step being provided on a surface of the semiconductor substrate between the gate electrode of the memory cell transistor and the gate electrode of the selective transistor such that a surface of the semiconductor substrate on a side of the memory cell transistor is positioned higher and a surface of the semiconductor substrate on a side of the selective transistor is positioned lower.

According to still another aspect of this invention, there is provided a non-volatile semiconductor memory device, comprising:

a semiconductor substrate;

a NAND cell unit formed on the semiconductor substrate and including at least two memory cell transistors, each of the memory cell transistors of the NAND cell unit including:

a tunnel insulation film formed on the semiconductor substrate;

a charge accumulation layer formed on the tunnel insulation film;

a block insulation film formed on the charge accumulation layer; and

a gate electrode formed on the block insulation film,

the charge accumulation layer is disconnected between the memory cell transistors,

selective transistors provided adjacent to the NAND cell unit, and the selective transistor including:

a gate insulation film having a single-layered structure formed of the same material as the material of the block insulation film of the memory cell transistor; and

a gate electrode formed on the gate insulation film,

wherein a step is provided on a surface of the semiconductor substrate between the gate electrode of the memory cell transistor and the gate electrode of the selective transistor such that a surface of the semiconductor substrate on a side of the memory cell transistor is higher and a surface of the semiconductor substrate on a side of the selective transistor is lower.

### BRIEF DESCRIPTION OF THE SEVERAL VIEWS OF THE DRAWING

FIG. 1 is a plan view showing a schematic configuration of a NAND-type non-volatile semiconductor memory device according to a first embodiment.

FIG. 2 is a cross-sectional view showing a schematic configuration of the NAND-type non-volatile semiconductor memory device according to the first embodiment.

FIGS. 3A-3H are cross-sectional views showing manufacturing steps of the NAND-type non-volatile semiconductor memory device according to the first embodiment.

FIG. 4 is a cross-sectional view showing a schematic configuration of a NAND-type non-volatile semiconductor memory device according to a second embodiment.

FIG. 5 is a cross-sectional view showing a schematic configuration of a NAND-type non-volatile semiconductor memory device according to a third embodiment.

### DETAILED DESCRIPTION OF THE INVENTION

Hereinafter, embodiments of the present invention will now be described in detail with reference to the accompanying drawings.

### First Embodiment

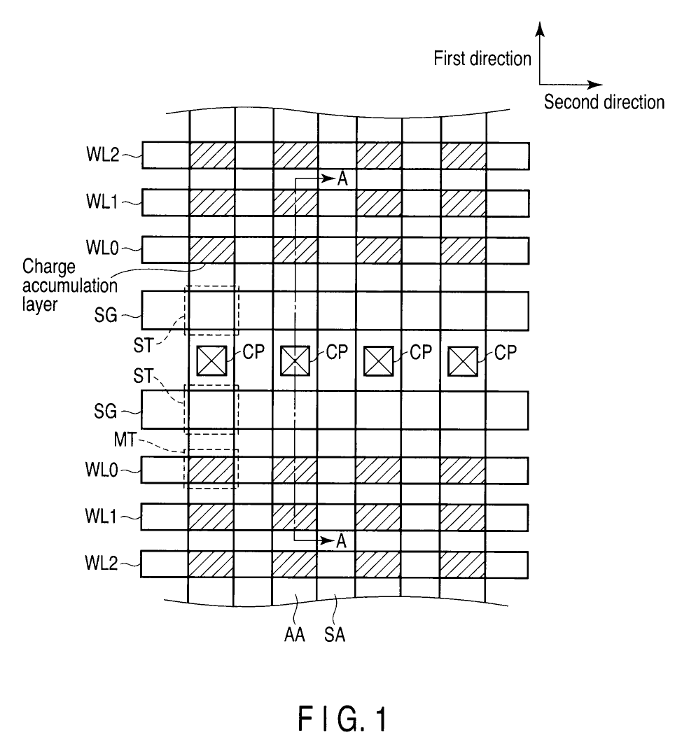

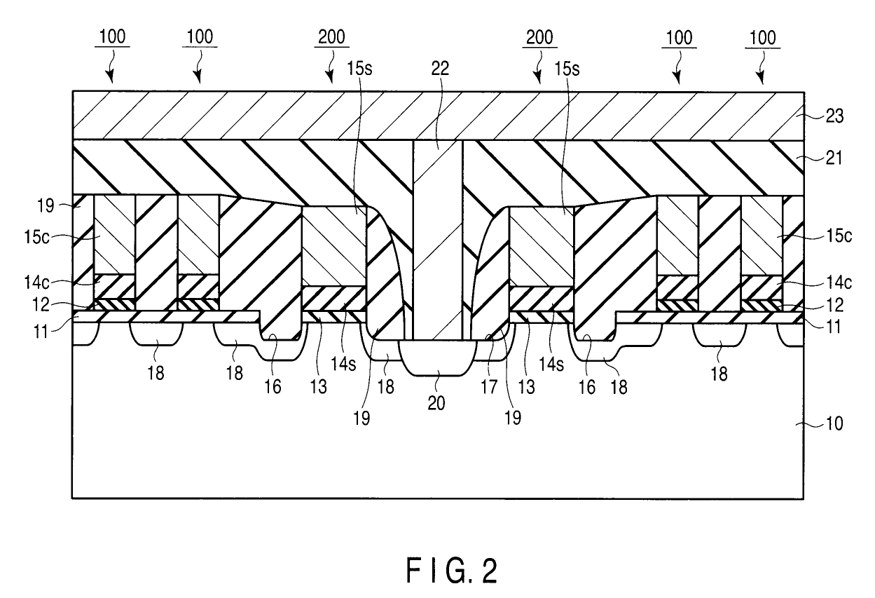

FIGS. 1 and 2 illustrate schematic configurations of a NAND-type non-volatile semiconductor memory device according to the first embodiment of the present invention. FIG. 1 is a plan view showing a configuration of the vicinity of a bit line contact, and FIG. 2 is a partial cross-sectional view of FIG. 1 along A-A. FIG. 2 specifically shows the cross-section of the memory cell transistor (MONOS cell) and the selective transistor in a gate lengthwise direction.

As shown in FIG. 1, a plurality of strips of element regions AA in a first direction are provided in a second direction crossing the first direction on a semiconductor substrate. An element separation region SA is formed between adjacent element regions AA. The element regions AA are electrically separated by the element separation region SA. The strips of word lines WL (WL0-WL2) and a select gate line SG are formed in the second direction and pass over the plurality of element regions AA on the semiconductor substrate. A memory cell transistor MT is provided in each of the regions at which the word lines WL and the element regions AA cross. A selective transistor ST is provided in each of the regions at which the selective gate lines SG and the element regions AA cross. An impurity diffusion layer, which is to be a source region or a drain region of each of the memory cell transistors MT and the selective transistors ST, is formed in parts of the element regions AA positioned between the word lines WL, the select gate lines, and the word line WL and the select gate line, which are adjacent to each other in the first direction.

An impurity diffusion layer formed in one of the element regions AA positioned between two of the select gate lines SG which are adjacent to each other in the first direction functions as a drain region of the selective transistor ST. A contact plug CP is formed on the drain region. The contact plug CP is connected to a bit line BL strip (not shown) provided in the first direction. Although not shown, an impurity diffusion layer formed in another element region AA between the other select gate lines SG which are adjacent to each other in the first direction functions as a source region of the selective transistor. A contact plug is formed on the source region and is connected to a source line, not shown.

As shown in FIG. 2, a selective transistor 200 (SG) is arranged at one end side of a memory unit (NAND cell unit) formed of a plurality of memory cell transistors 100 (MT) arranged in series, and the selective transistors 200 are arranged to be opposed to each other interposing a bit line contact (CP). Although not shown, the other end side of the memory cell unit is connected to a source line via another selective transistor, and a memory cell array formed of a memory cell unit and a selective transistor.

As shown in FIG. 2, each of the memory cell transistors 100 is configured by forming a tunnel insulation film 11 on a silicon substrate (semiconductor substrate) 10, forming a charge accumulation layer 12, a block insulation film 14c, and a gate electrode 15c on a part of the tunnel insulation film 11, and further forming a source/drain region 18 in a surface part of the substrate 10. The charge accumulation layers 12 of adjacent memory cell transistors 100 are configured to be disconnected from each other. Further, the selective transistor 200 is configured by forming a first gate insulation film 13 on the silicon substrate 10, forming a second gate insulation film 14s, and a gate electrode 15s on the first gate insulation film 13, and further forming a source/drain region 18 in the surface part of the substrate 10.

In FIG. 2, the tunnel insulation film 11 and the first gate insulation film 13 are different insulation films formed separately, and the block insulation film 14c and the second gate insulation film 14s are the same insulation film formed simultaneously. Further, the gate electrode 15c and the gate electrode 15s are formed simultaneously, and of the same conductive material.

A step 16 is provided on a surface of the semiconductor substrate between the gate electrode 15c of the memory cell transistor 100 and the gate electrode 15s of the selective transistor 200, such that the surface of the step 16 is positioned higher on the side of the memory cell transistor 100 and lower on the side of the selective transistor 200. That is, on the side of the selective transistor 200, a step is provided between the surface of the substrate interposing a gate electrode part formed of the first and second gate insulation films 13, 14s and the gate electrode 15s and the surface of the substrate below the gate electrode part, and the surface of the substrate interposing the gate electrode part is formed lower than the surface of the substrate below the gate electrode part. Further, a step 17 is formed on the surface of the semiconductor substrate 10 between the gate electrodes 15s of adjacent selective transistors 200, such that the surface of the step 17 is positioned lower than the surface of the semiconductor substrate on the side of the memory cell transistor 100, as in the case of the step 16.

On the surface of the semiconductor substrate interposing the gate electrode part of the memory cell transistor 100 and on the surface of the substrate interposing the gate electrode part of the selective transistor 200, a source/drain region 18 doped with an impurity in small concentrations is formed. An insulation film 19 is embedded between adjacent memory cell transistors 100, and between the memory cell transistor 100 and the selective transistor 200. Further, an insulation film 19 is formed as a sidewall film on a side surface of a side of the gate electrode 15c of the selective transistors 200 which are opposed to each other. Further, a highly concentrated source/drain region 20 is formed between adjacent selective transistors 200.

An interlayer insulation film 21 is formed on the substrate on which the above-described elements are formed. A contact plug 22 which contacts the source/drain region 20 is embedded in the interlayer insulation film 21. Further, on the interlayer insulation film 21, a bit line 23 which contacts the contact plug 22 is formed.

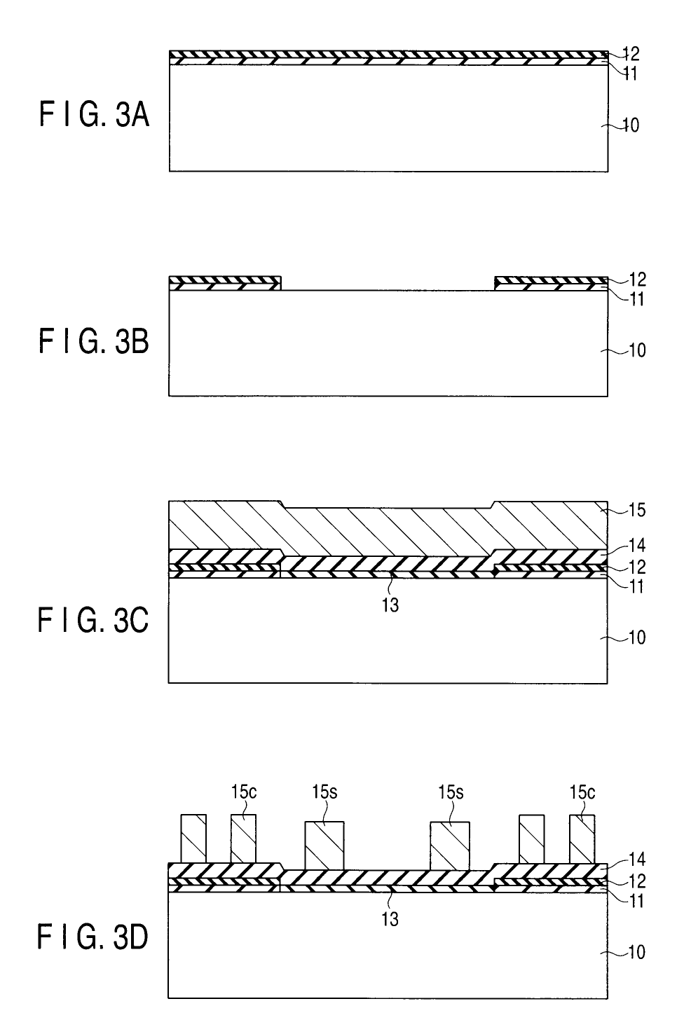

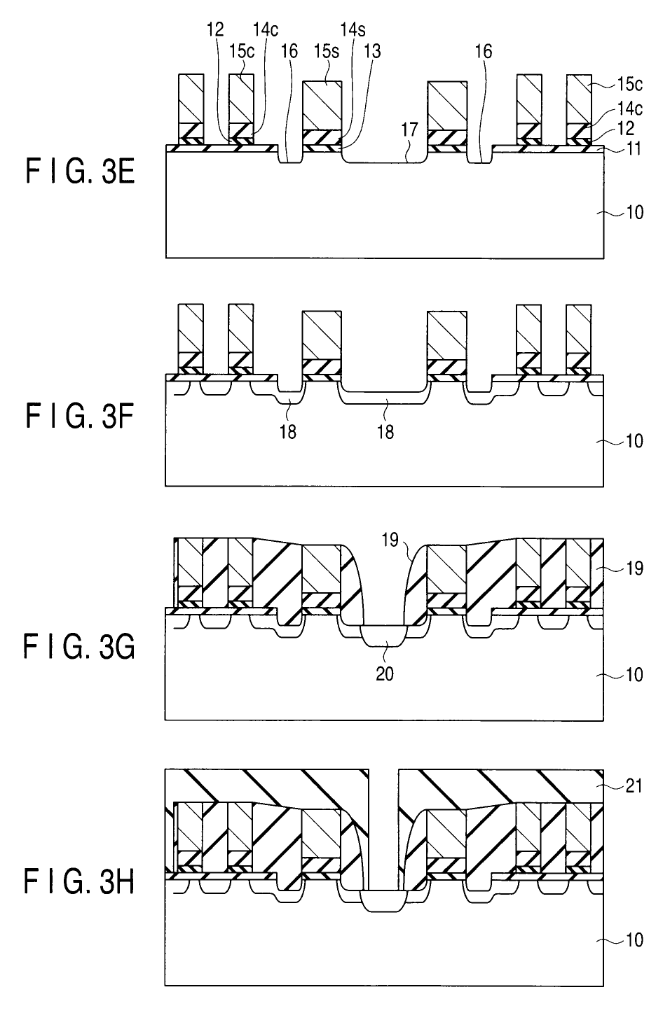

An example of a method of manufacturing the non-volatile semiconductor memory device according to the present embodiment will now be described with reference to FIGS. 3A-3H.

Although not shown, a well-channel region of the memory cell transistor 100 and the selective transistor 200 is formed in the silicon substrate 10 through ion implantation.

As shown in FIG. 3A, a tunnel insulation film 11 of the memory cell transistor 100 is formed on the surface of the silicon substrate 10 through thermal oxidation, for example. After that, a silicon nitride film, for example, is deposited to form a charge accumulation layer 12. Assume that the film thickness of the tunnel insulation film 11 is 4 nm, for example, and the film thickness of the charge accumulation layer 12 is 5 nm, for example.

As shown in FIG. 3B, a resist pattern, not shown, having an opening in a region which is to be a selective transistor 200 is formed through a lithography process, and the tunnel insulation film 11 and the charge accumulation layer 12 are removed from that region. Then the resist pattern is removed.

As shown in FIG. 3C, a first gate insulation film 13 of the selective transistor is formed to have a thickness of 4 nm, for example, on a surface of the silicon substrate 10 through thermal oxidation. In this case, an oxide film is not formed on the charge accumulation layer 12 of the memory cell transistor 100. After that, an insulation film 14, which is to be a block insulation film 14c of the memory cell transistor 100 and a second gate insulation film 14s of the selective transistor 200, is formed to have a thickness of 15 nm, for example, of an alumina (Al₂O₃) film, for example, on the charge accumulation layer 12 and the first gate insulation film 13. After that, a conductive layer 15, which is to be the gate electrode 15c of the memory cell transistor and the gate electrode 15s of the selective transistor 200, is formed of a polysilicon film, for example, on the insulation film 14 to have a thickness of 50 nm, for example.

The conductive layer 15 is not necessarily limited to polysilicon, and may have a stacked structure of TaN/WN/W, for example.

As shown in FIG. 3D, the conductive layer 15 is etched in gate patterns through a lithography process. Thereby, the gate electrode 15c of the memory cell transistor 100 and the gate electrode 15s of the selective transistor 200 are formed.

As shown in FIG. 3E, by etching the insulation film 14 through RIE using the gate electrode 15c of the memory cell transistor 100 and the gate electrode 15s of the selective transistor 200 as masks, the block insulation film 14c of the memory cell transistor 100 and the second gate insulation film 14s of the selective transistor 200 are formed. In this state, the etching is stopped at the charge accumulation layer 12 in the memory cell transistor 100, but overetching occurs in the selective transistor 200 because of lack of the charge accumulation layer 12. As a result, the upper part on all of the first gate insulation film 13 is etched.

As an etchant of Al₂O₃ used as the insulation film 14, a mixed gas of C₄F₈, O₂ and Co or a mixed gas formed by arbitrarily combining a gas such as CH₄, O or H₂ and a gas such as Cl₂, HCl, or BCl₃ may be used. Further, etching may be performed through REI using the gas obtained by adding an Ar gas to the mixed gas.

Following that, the charge accumulation layer 12 between the memory cell transistors 100 is etched and the charge accumulation layer 12 between the memory cell transistors 100 is disconnected. In this state, in the part of the selective transistor 20, the upper part or all of the first gate insulation film 13 has already been etched. As a result, it is very difficult to keep the surface of the silicon substrate 10 between the gate electrode 15c of the memory cell transistor 100 and the gate electrode 15s of the selective transistor 200 in a flat state.

The etching conditions are therefore adjusted such that the step 16 is formed on the surface of the silicon substrate 10 on the side of the selective transistor between the gate electrode 15c of the memory cell transistor 100 and the gate electrode 15s of the selective transistor 200, and such that the step 17 is formed on the surface of the silicon substrate 10 between the gate electrodes 15s of adjacent selective transistors 200. That is, the charge accumulation layer 12 is etched and removed through the RIE method, for example, under a condition that the etching selection ratio of the charge accumulation layer 12 to the tunnel insulation film 11 is sufficiently large and the etching selection ratio of the charge accumulation layer 12 to the silicon substrate 10 is slightly large.

As a result, grooves (steps) 16, 17 having a depth of 10-20 nm are formed in a surface part of the silicon substrate 10. In this state, the charge accumulation layer 12 between the memory cell transistors 100 can be completely disconnected.

Too great a depth of the steps 16, 17 causes a bad effect on transistor characteristics of the selective transistor 200. Therefore, the depth of the steps 16, 17 should preferably be smaller than the film thickness that adds the first gate insulation film 13 and second gate insulation film 14.

As shown in FIG. 3F, the surface part of the substrate 10 between the gate electrodes of adjacent memory cell transistors 100, between the gate electrode of the memory cell transistor 200 and the gate electrode of the selective transistor 100, and gate electrodes of adjacent selective transistors 200 is doped with an n-type impurity. Thereby, a low-concentration source/drain region 18 is formed.

As shown in FIG. 3G, an insulation film 19 formed of a TEOS film, for example, is embedded between the gate electrodes of adjacent memory cell transistors 100, between the gate electrode of the memory cell transistor 100 and the gate electrode of the selective transistor 200, and between the gate electrodes of adjacent selective transistors 200. Further, the insulation film 19 is etched to form a sidewall on a side surface of a side of the gate electrode 15c of the selective transistors 200 which are opposed to each other, and then a high-concentrated source/drain region 20 is formed as a mask of the insulation film 19 and the gate electrode 15c, 15s. Although not shown, the polysilicon film forming the gate electrodes 15c, 15s is changed to Co silicide, and an insulation film used as a stopper at the time of etching of a contact opening is deposited, as necessary.

As shown in FIG. 3H, the interlayer insulation film 21 is formed of a BPSG film, for example, and then a contact hole is made through a lithography process.

A contact plug 22 is formed using W, for example, and then a bit line 23 is formed using Cu, for example, thereby obtaining the configuration shown in FIGS. 1 and 2. After that, by forming an upper wiring layer using a generally known method, the non-volatile semiconductor memory is completed.

Thus, according to the present embodiment, the charge accumulation layer 12 is disconnected between adjacent memory cell transistors 100. This prevents a charge from moving between the memory cell transistors 100 and prevents reliability of the memory cell transistors 100 from deteriorating. Further, the step 16 is formed only on the side of the selective transistor 200 on the surface of the silicon substrate 10 between the gate electrode 15c of the memory cell transistor 100 and the gate electrode 15s of the selective transistor 200, and a step is not formed on the side of the memory cell transistor 100. Therefore, the characteristics of the memory cell transistor 100 are not deteriorated by a short-channel effect, and the reliability of the memory cell transistor 100 can be prevented from deteriorating.

Further, since the gate insulation film of the selective transistor 200 does not include a charge accumulation layer, the threshold voltage of the selective transistor 200 does not change due to the voltage stress applied to the gate electrode of the selective transistor 200 at the time of reading. Thereby, the reliability of the selective transistor 200 can be prevented from deteriorating.

A second gate insulation film 14s formed of the same material as that of the block insulation film 14C of the memory cell transistor 100 is included in a part of the gate insulation film of the selective transistor 200. Thereby, the block insulation film 14c of the memory cell transistor 100 and at least a part of the gate insulation film of the selective transistor can be simultaneously performed, which results in a decreased manufacturing cost.

Further, since the gate electrode 15C of the memory cell transistor 100 and the gate electrode 15s of the selective transistor 200 are formed of the same conductive layer and therefore can be simultaneously processed, an increase in manufacturing steps can be suppressed and the manufacturing cost can be decreased.

Although the short-channel effect on the selective transistor 200 is large due to the step, the gate length of the selective transistor 200 is greater than the gate length of the memory cell transistor 100. Therefore, the selective transistor 200 is not easily affected by the short-channel effect. Therefore, existence of the step does not cause a serious problem.

That is, the gate insulation film of the selective transistor 200 can be configured to exclude a charge accumulation layer in the gate insulation film of the selective transistor 200 without increasing a manufacturing cost, and thereby the reliability of the selective transistor 200 can be improved and the manufacturing cost can be decreased.

In the present embodiment, since the steps 16, 17 are formed in a region interposing the gate electrode part of the selective transistor 200, an impurity diffusion layer extending toward the end part below the gate electrode part is formed by diffusion from an impurity ion-implanted into the bottom part of the step. Therefore, compared to diffusion from the side as in the case of the impurity diffusion layer 18 below the gate electrode part of the memory cell transistor 100, the impurity concentration of the end part below the gate electrode part of the selective transistor 200 is low. Thereby, advantages which will be described below can be obtained.

The gate electrodes of the selective transistors 200 are commonly connected to a plurality of memory cell units. A high voltage is applied between the gate electrode and a channel region of the selective cell at the time of writing of a selected memory cell (selective cell) of the selected memory cell unit. In a non-selective memory cell unit, on the other hand, a cell (non-selective cell) connected to the same word line as that of the selective cell must be prevented from being written. Accordingly, the selective transistor 200 is cut off, and the electric potential of the channel region and the impurity diffusion layer 18 is increased by the boost effect. Thereby, writing is prevented. In this state, when the electric potential of the channel region and the impurity diffusion layer 18 in the non-selective cell decreases due to a band-to-band (BB) leak between the impurity diffusion layer 18 of the selective transistor 200 and the semiconductor substrate 10, error writing occurs.

In the present embodiment, on the other hand, due to the low impurity concentration of the diffusion layer below the gate electrode part of the selective transistor 200, a junction will be made between the n-type layer with a low impurity concentration and the p-type layer of the semiconductor substrate 10, and the BB leak becomes small. It is therefore possible to prevent decreasing the threshold voltage in the non-selective cell from, and suppress error writing.

### Second Embodiment

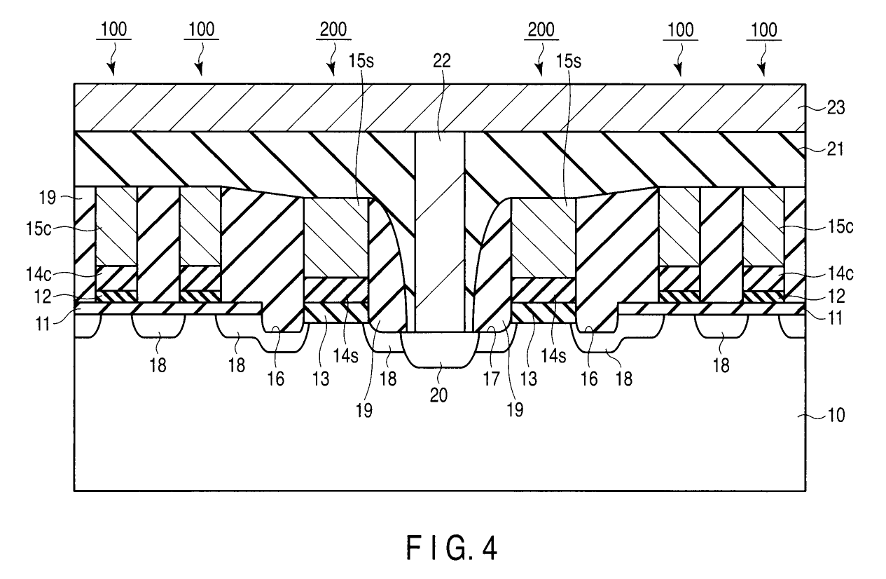

FIG. 4 is a cross-sectional view showing a schematic configuration of a NAND-type non-volatile semiconductor memory device according to a second embodiment of the present invention, and more particularly, a cross section of a memory cell transistor and a selective transistor in a gate length direction. The structural elements that are the same as those of FIG. 2 will be denoted by the same reference numerals and detailed descriptions of such elements will be omitted.

The basic configuration is the same as that of the above-described first embodiment. The present embodiment is different from the first embodiment in that the interface between the first gate insulation film 13 of the selective transistor 200 and the semiconductor substrate 10 is positioned lower than the interface between the tunnel insulation film 11 of the memory cell transistor 100 and the semiconductor substrate 10.

This configuration may be obtained by increasing the oxidation amount of the surface of the semiconductor substrate 10 exposed in the step of FIG. 3B and increasing the film thickness of the first gate insulation film 13 of the selective transistor 200. Further, the configuration may also be obtained by etching the tunnel insulation film 11 and then etching the surface of the semiconductor substrate 10 in the step of FIG. 3B.

In the present embodiment with the above-described configuration, the depth of the step 16 from the interface between the first gate insulation film 13 of the selective transistor 200 and the silicon substrate 10 can be made small. Thereby, the advantage of improving the characteristics of the selective transistor 200 as well as the effect which can be obtained from the first embodiment can be obtained.

### Third Embodiment

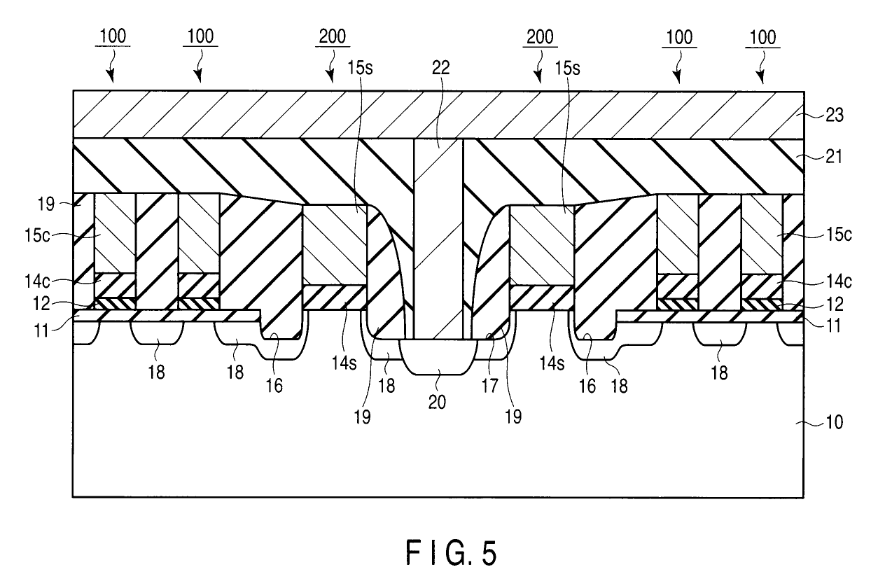

FIG. 5 shows a cross-sectional view showing a schematic configuration of a NAND-type non-volatile semiconductor memory device according to a third embodiment of the present invention, and more particularly, a cross section of a memory cell transistor and a selective transistor in a gate length direction. The structural elements that are the same as those of FIG. 2 will be denoted by the same reference numerals and detailed descriptions of such elements will be omitted.

The basic configuration is the same as the first embodiment. The present embodiment is different from the first embodiment in that the second gate insulation film 14s of the selective transistor 200 is configured by a single layer.

The configuration of the present embodiment can be obtained by forming only the insulation film 14, and not forming the first gate insulation film 13 in the selective transistor 200 in the step of FIG. 3C.

With this configuration, as well as the advantage that can be obtained from the first embodiment, the following advantage can also be obtained. That is, in the present embodiment, since the first gate insulation film 13 of the selective transistor 200 is not formed, the manufacturing cost can be decreased, as compared to the first embodiment. Since the first gate insulation film 13 does not exist, however, the steps 16, 17 tend to be formed too deep. In order to prevent this, the etchant should be properly selected at the time of selective etching of the charge accumulation layer 12 and the insulation film 14 through RIE, for example,

### (Modification)

The present invention is not limited to the above-described embodiments. In the embodiments, a silicon nitride film is used as a charge accumulation layer, but a high-dielectric insulation film such as hafnium film may also be used. Further, the block insulation film is not limited to alumina, and other insulation films may be used. Moreover, the material for the semiconductor substrate is not limited to silicon, and other semiconductor materials may also be used.

Further, the depth of the step (groove) formed in the surface region of the semiconductor substrate may be changed as appropriate in a range smaller than the film thickness of the gate insulation film of the selective transistor. Further, the film formation method and etching method of the charge accumulation layer, block insulation film, the gate insulation film, and the like are not limited to those described above and can be changed as appropriate.

In the embodiments, the descriptions have been made with regard to the case where the block insulation film 14c and the second gate insulation film 14s are the same insulation film formed simultaneously, and the gate electrode 15c and the gate electrode 15s are the same conductive material formed simultaneously, but the present invention is not limited to this case.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A non-volatile semiconductor memory device, comprising:
a semiconductor substrate; and
a memory cell array provided on the semiconductor substrate and formed of a memory cell unit including at least two memory cell transistors and a selective transistor provided adjacent to the memory cell unit,
wherein the memory cell transistor includes a tunnel insulation film formed on the semiconductor substrate, a charge accumulation layer formed on the tunnel insulation film, a block insulation film formed on the charge accumulation layer, and a gate electrode formed on the block insulation film, the charge accumulation layer being disconnected between the memory cell transistors,
the selective transistor includes a gate insulation film including a film made of the same material as the block insulation film and formed on the semiconductor substrate, and a gate electrode formed on the gate insulation film, and
a step is provided on a surface of the semiconductor substrate between the gate electrode of the memory cell transistor and the gate electrode of the selective transistor, the step being formed such that a surface of the semiconductor substrate on a side of the memory cell transistor is positioned higher and a surface of the semiconductor substrate on a side of the selective transistor is positioned lower.

2. The device according to claim 1, wherein the gate electrode of the memory cell transistor and the gate electrode of the selective transistor are formed of the same conductive layer.

3. The device according to claim 1, wherein the step height is smaller than a film thickness of the gate insulation film of the selective transistor.

4. The device according to claim 1, wherein an interface between the gate insulation film of the selective transistor and the semiconductor substrate is positioned lower than an interface between a tunnel insulation film of the memory cell transistor and the semiconductor substrate.

5. The device according to claim 1, wherein a diffusion layer is formed below the gate electrode of each of the selective transistor and the memory cell transistor in an end part of the gate electrode of each of the selective transistor and the memory cell transistor, and an impurity concentration of the diffusion layer below the gate electrode of the selective transistor is lower than that of the diffusion layer below the gate electrode of the memory cell transistor.

6. The device according to claim 1, wherein the gate insulation film of the selective transistor has a two-layered structure including a first gate insulation film formed of a layer different from a material of the tunnel insulation film of the memory cell transistor and a second gate insulation film formed of the same material as the material of the block insulation film of the memory cell transistor.

7. The device according to claim 1, wherein the gate insulation film of the selective transistor has a single-layered structure formed of the same material as the material of the block insulation film of the memory cell transistor.

8. The device according to claim 1, wherein the memory cell unit is a NAND cell unit in which the memory cell transistors are connected in series.

9. A non-volatile semiconductor memory device, comprising:
a semiconductor substrate;
a NAND cell unit provided on the semiconductor substrate and including at least two memory cell transistors, each of the memory cell transistors of the NAND cell unit including:
a tunnel insulation film formed on the semiconductor substrate;
a charge accumulation layer formed on the tunnel insulation film;
a block insulation film formed on the charge accumulation layer; and
a gate electrode formed on the block insulation film,
the charge accumulation layer being disconnected between the memory cell transistors,
a selective transistors provided adjacent to the NAND cell unit, the selective transistor including:
a gate insulation film formed of a two-layered structure including a first gate insulation film formed of a layer different from a material of the tunnel insulation film of the memory cell transistor and a second gate insulation film formed of the same material as the material of the block insulation film of the memory cell transistor; and
a gate electrode formed on the gate insulation film,
wherein a step being provided on a surface of the semiconductor substrate between the gate electrode of the memory cell transistor and the gate electrode of the selective transistor such that a surface of the semiconductor substrate on a side of the memory cell transistor is positioned higher and a surface of the semiconductor substrate on a side of the selective transistor is positioned lower.

10. The device according to claim 9, wherein the gate electrode of the memory cell transistor and the gate electrode of the selective transistor are formed of the same conductive layer.

11. The device according to claim 9, wherein the step height is smaller than a film thickness of the gate insulation film of the selective transistor.

12. The device according to claim 9, wherein an interface between the gate insulation film of the selective transistor and the semiconductor substrate is positioned lower than an interface between the tunnel insulation film of the memory cell transistor and the semiconductor substrate.

13. The device according to claim 9, wherein a diffusion layer is formed below the gate electrode of each of the selective transistor and the memory cell transistor in an end part of the gate electrode of each of the selective transistor and the memory cell transistor, and an impurity concentration of the diffusion layer below the gate electrode of the selective transistor is lower than that of the diffusion layer below the gate electrode of the memory cell transistor.

14. A non-volatile semiconductor memory device, comprising:
a semiconductor substrate;
a NAND cell unit formed on the semiconductor substrate and including at least two memory cell transistors, each of the memory cell transistors of the NAND cell unit including:
a tunnel insulation film formed on the semiconductor substrate;
a charge accumulation layer formed on the tunnel insulation film;
a block insulation film formed on the charge accumulation layer; and
a gate electrode formed on the block insulation film,
the charge accumulation layer is disconnected between the memory cell transistors,
selective transistors provided adjacent to the NAND cell unit, and the selective transistor including:
a gate insulation film having a single-layered structure formed of the same material as the material of the block insulation film of the memory cell transistor; and
a gate electrode formed on the gate insulation film,
wherein a step is provided on a surface of the semiconductor substrate between the gate electrode of the memory cell transistor and the gate electrode of the selective transistor such that a surface of the semiconductor substrate on a side of the memory cell transistor is higher and a surface of the semiconductor substrate on a side of the selective transistor is lower.

15. The device according to claim 14, wherein the gate electrode of the memory cell transistor and the gate electrode of the selective transistor are formed of the same conductive layer.

16. The device according to claim 14, wherein the step height is smaller than a film thickness of the gate insulation film of the selective transistor.

17. The device according to claim 14, wherein an interface between the gate insulation film of the selective transistor and the semiconductor substrate is positioned lower than an interface between the tunnel insulation film of the memory cell transistor and the semiconductor substrate.

18. The device according to claim 14, wherein a diffusion layer is formed below the gate electrode of each of the selective transistor and the memory cell transistor in an end part of each of the gate electrodes of the selective transistor and the memory cell transistor, and an impurity concentration of the diffusion layer below the gate electrode of the selective transistor is lower than that of the diffusion layer below the gate electrode of the memory cell transistor.
